(19) United States
(12) Patent Application Publication
(10) Pub. No.: US 2020/0214168 A1
(43) Pub. Date: Jul. 2, 2020

(54) VARIABLE IN LINE VOLTAGE BOOSTER USING NATIVE POWER SYSTEM OR INTERNAL MODULATION

(71) Applicant: BATTERY STREET ENERGY, INC., Seattle, WA (US)

(72) Inventor: Peter Bocek, Seattle, WA (US)

(21) Appl. No.: 16/538,377

(22) Filed: Aug. 12, 2019

Related U.S. Application Data
(60) Provisional application No. 62/717,432, filed on Aug. 10, 2018.

(51) Int. Cl. H05K 7/20; H05K 7/18; H05K 7/02; H02M 3/158

(52) U.S. Cl. CPC H05K 7/2089; H02M 3/1582; H05K 7/02; H05K 7/18

(57) ABSTRACT

A Variable In Line Voltage Booster includes a housing; at least one set of input connectors; at least one set of output connectors; a plurality of power converters carried by at least one power converter board and coupled between the at least one set of input connectors and the at least one set of output connectors and operable to adjust a voltage received via the at least one set of input connectors to supply a voltage via the at least one set of output connectors; and a control board carrying a set of control circuitry, the control circuitry communicatively coupled to control the plurality of power converters. The housing may be rack mountable, and may include inlet vents and exhaust vents, either with or with fans. A control board may be spaced from one or more power converter board, which carry power electronics (e.g., MOSFETS, BJTs) via one or more posts

The various embodiments described above can be combined to provide further embodiments. All of the commonly assigned US patent application publications, US patent applications, foreign patents, foreign patent applications and non-patent publications referred to in this specification and/or listed in the Application Data Sheet, including but not limited to U.S. Provisional Application No. 62/717,432, filed on Aug. 10, 2018 is incorporated herein by reference, in their entirety.

### TECHNICAL FIELD

The present disclosure is generally related to power converters and operation of same, for instance to manage a voltage output from Direct Current (DC) power plants.

### BACKGROUND

A boost converter (step-up converter) is a DC-to-DC power converter that steps up voltage (while stepping down current) received from an input source (i.e., supply) and delivered to an output (i.e., load). A DC-to-DC boost converter may take the form of a switched-mode power supply (SMPS) including at least two semiconductors (a diode and a transistor) and at least one energy storage element: e.g., a capacitor, inductor, or the two in combination. DC-to-DC boost converters typically include one or more filters to reduce voltage ripple. The filters may comprise capacitors, sometimes in combination with inductors. The filters may, for example, be added on an output side and denominated as a load-side filter and, or add on an input side and denominated as a supply-side filter. Power for the DC-to-DC boost converter can come from any suitable DC power sources, for example batteries, super- or ultra-capacitors, solar panels, rectifiers and DC generators. A process that changes one DC voltage to a different DC voltage is called DC to DC conversion. A boost converter is a DC-to-DC converter with an output voltage greater than the source voltage. A ‘boost’ converter is commonly referred to as a step-up converter. In contrast, a DC-to-DC convert that with an output voltage less than the source voltage is a ‘buck’ converter, and commonly referred to as a step-down converter.

### SUMMARY

The present disclosure generally relates to power converters and operation of power converters, for instance to manage a voltage output from Direct Current (DC) power sources. This can be accomplished by modulating boost converter voltage and/or working in conjunction with native power system voltage adjustments. One exemplary configuration includes a “static” boost post converter (e.g., 5 V boost converter) and overall system voltage adjustments via commands from a booster measurement system. Doing so allows for savings in cost and reduces system complexity, as adjusting either voltage source (i.e., static boost post converter and, or the native power system) can regulate a “total” system voltage.

Apparatus and associated methods involve voltage converter/booster components housed in a standard Rack Unit (RU) module for installation in a wide variety of equipment housing types. In some implementations, a method for voltage conversion and/or boosting may include single step voltage adjustment via a fixed (ON/OFF) voltage output. Other implementations may include stepped voltage boosting in increments. Various implementations may include features to accommodate multiple DC power sources, bypass switching, and/or disconnection via Field-Effect Transistor (FET) or Metal Oxide Semiconductor FET (MOSFET), voltage target control, and/or linear voltage modulation. Various implementations may include flexible and expandable printed circuit board (PCB) layouts, so that power board module(s) is/(are) totally independent of a control board and can operate as a stand-alone system. Other implementations may accommodate user accessible front panel displays and/or user controls, and/or back panel connection points.

Various implementations or embodiments may achieve one or more advantages. For example, utilizing commercially available electronic parts combined with simple circuit design achieves various manufacturing economies. The RU module design for the Variable In Line Voltage Booster simplifies installation and affords additional economy for inspection, replacement and/or future expansion. The overall design achieves an expected high Mean Time Between Failure of approximately 250,000 hours because of the utilization of simple mechanical design resulting in low waste heat and minimized thermal dissipation requirements. Selective use of connector and fuse types further minimizes costs and simplifies electrical terminations. In some implementations, when used with an external control device or Programmable Logic Controller (PLC) or linear loop control, the Variable In Line Voltage Booster can accommodate user or customer specified parameters via internally provisioned proprietary algorithm(s).

Some implementations or embodiments may package a plurality of power modules into single Variable In Line Voltage Booster housing.

Some implementations, the Variable In Line Voltage Booster may have an adjustable voltage range to match the input voltage range of customer equipment, for example customer communications equipment.

The details of various implementations and embodiments are set forth in the accompanying drawings and the description below. Other features and advantages will be apparent from the description and drawings, and from the claims.

### BRIEF DESCRIPTION OF THE DRAWINGS

FIG. 1A is a front, top isometric view that shows an exemplary Variable In Line Voltage Booster, according to at least one illustrated implementation, with fan ports, control interface and status indicator lights visible.

FIG. 1B is a rear, top isometric view that shows the exemplary Variable In Line Voltage Booster of FIG. 1A, with electrical termination panel and connector hardware visible.

FIG. 2 is a top, front isometric view that shows an exemplary Variable In Line Voltage Booster, with circuitry as discrete electronic components housed within its standardized rack unit housing.

FIG. 3A is a schematic drawing of a Variable In Line Voltage Booster, according to at least one illustrated implementation, with connectors, busbars, standoffs, and circuitry that can be housed within its standardized rack unit housing.

FIG. 3B is a schedule of up-plated holes associated with a printed circuit board which carries circuitry, according to at least one illustrated implementation.

FIG. 3C is a side elevational view showing a control board (e.g., printed circuit board (PCB)) stacked above a plurality of converter boards (PCBs), according to at least one illustrated implementation.

FIG. 4 is an electrical schematic diagram that shows Variable In Line Voltage Booster circuit, according to at least one illustrated implementation, for a power board module.

FIG. 5A a mask work diagram showing a Variable In Line Voltage Booster PCB board mask, according to at least one illustrated implementation.

FIG. 5B is a top plan view of a Variable In Line Voltage Booster power module, according to at least one illustrated implementation.

FIG. 6 is an isometric view of an environment including a rack that shows a base station installation of a Variable In Line Voltage Booster, according to at least one illustrated implementation.

Like reference symbols in the various drawings indicate similar or identical structures.

### DETAILED DESCRIPTION OF ILLUSTRATIVE EMBODIMENTS

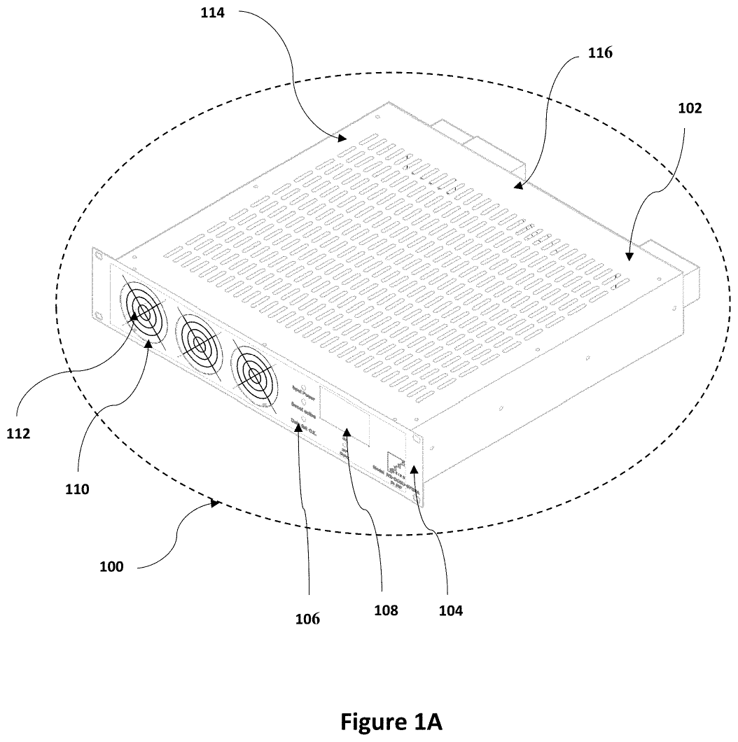

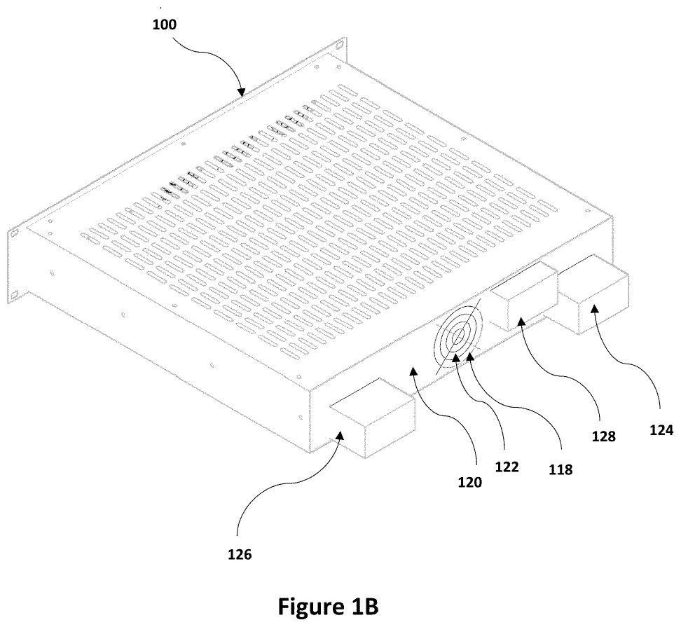

FIGS. 1A and 1B show a Variable In Line Voltage Booster 100, according to at least one illustrated implementation.

As best illustrated in FIG. 1A, the Variable In Line Voltage Booster 100 includes a housing 102, with a front panel 104. The front panel 104 includes a set of front panel controls 106, a display 108 and a number of intake ports 110 (only one called out) with associated cooling fans 112 (only one called out). In the depicted example, user configurable front panel controls 106 allow access to operational functions and operation of the Variable In Line Voltage Booster 100, including switching the Variable In Line Voltage Booster 100 between ON and OFF states.

The intake ports 110 and cooling fans 112 provide for air intake to assist with cooling of internal components (e.g., electronics, not visible in FIGS. 1A, 1B). Air flow is directed across internal components and is able to passively vent or exhaust through a plurality of exhaust vents 114 positioned on a top 116 of the housing 102.

The exhaust vents 114 in the top 116 of the housing 102 may be distributed evenly and uniform heat dispersion from an interior of the housing 102 to an exterior environment. The intake ports 110 and exhaust vents 114 may permit air circulation to and from the internal components (not visible in FIGS. 1A, 1B) of the Variable In Line Voltage Booster 100. In some circumstances, the intake ports 110 and exhaust vents 114 may prevent overheating of the internal components of the Variable In Line Voltage Booster 100, especially electrical and electronic circuitry housed within the housing 102.

As best illustrated in FIG. 1B, the Variable In Line Voltage Booster 100 may additionally or alternatively include a rear exhaust vent 118 positioned at a rear 120 of the housing 102, which facilitates removal of heat generated by the internal components from the interior of the housing 102. The rear exhaust vent 118 may passively allow exhausting of heat from the interior to an external environment. Optionally, the Variable In Line Voltage Booster 100 may additionally or alternatively include exhaust fan 122 positioned at the rear 120 of the housing 102, for instance located in or adjacent or concentrically with the rear exhaust vent 118, which enhances the ability to removal of heat generated by the internal components (not visible in FIGS. 1A, 1B) from the interior of the housing 102, actively increasing cooling capacity.

As best illustrated in FIG. 1B, the Variable In Line Voltage Booster 100 may include sets of input connectors 124 and output connectors 126. In the depicted example, the output connectors 126 are strategically positioned to allow convenient connection of the output connectors 126 even when a plurality of Variable In Line Voltage Boosters 100 are stacked on or alongside of each other, such as in a closet, cabinet, or rack. The input connectors 124 may be mounted on the opposite side, to allow ease of connectivity while clearly separating the input connectors 124 from the output connectors 126.

In the depicted example, a set of boost connections 128 are illustrated positioned near a middle of a plane of the rear 120 of the Variable In Line Voltage Booster 100 housing, facilitating vertical connections from top or bottom edges thereof.

The Variable In Line Voltage Booster 100 may include one or more communications interfaces (e.g., communications ports, radios) to provide communications with external devices may include a monitor/control module that includes sensing components for managing the operation and function of the Variable In Line Voltage Booster 100. The communications interfaces may, for example, include one or more of RS232 ports and/or controllers, USB ports and/or controllers, CAN bus ports and/or controllers, wireless radios (e.g., Bluetooth radio or transceiver and associated antennas).

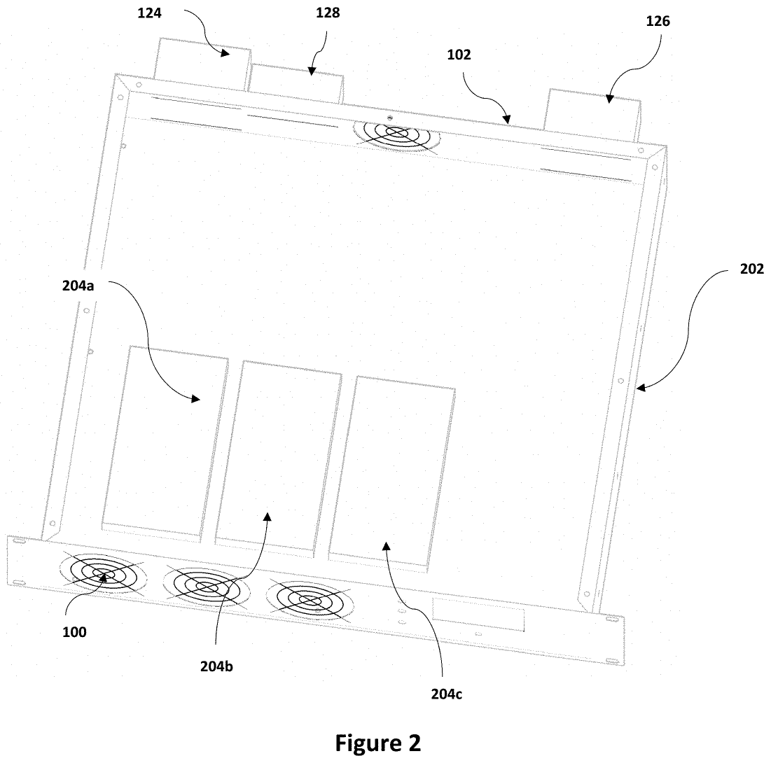

FIG. 2 shows an interior 200 of the housing 102 of the Variable In Line Voltage Booster 100, including circuitry 202 and other structures. The circuitry 202 is illustrated as a number of discrete electronic components that are received within the housing 102.

In some implementations, Variable In Line Voltage Booster 100 may include a plurality (e.g., 3 or more) converter modules 204a, 204b, 204c (three shown, collectively 204) to control voltage boost at a number of distinct voltages (e.g., 2V, 3V, 5V or 8V or other fixed values). These converter modules 204 may be electrically coupled or coupleable in various parallel configurations to achieve voltage boost currents as needed to correct system demands and/or to enhance fault tolerance.

Additionally or alternatively, some implementations may include converter modules 204 electrically coupled or coupleable in parallel to allow, for example, up to 180 A of a bulk voltage boost.

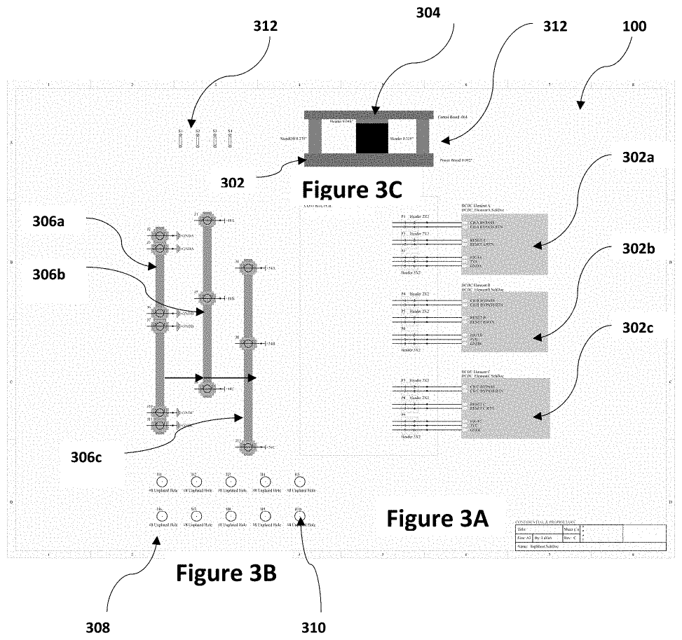

FIG. 3A shows at least some components 300 of the Variable In Line Voltage Booster 100, according to at least one illustrated implementation.

The Variable In Line Voltage Booster 100 may, for example include one or more converter boards 302a, 302b, 302c (three shown, collectively 302), one or more control boards 304 (one shown), a number of connecting busbars 306a, 306b, 306c (three shown, collectively 306).

FIG. 3B shows a schedule 308 for un-plated holes 310 (ten illustrated, only once called out).

FIG. 3C shows the control board 304 advantageously mounted above the converter boards 302, for example utilizing standard PCB posts 312 for separation.

In some configurations, the control board 304 may allow for linear voltage modulation based on a specific algorithm developed for all use cases.

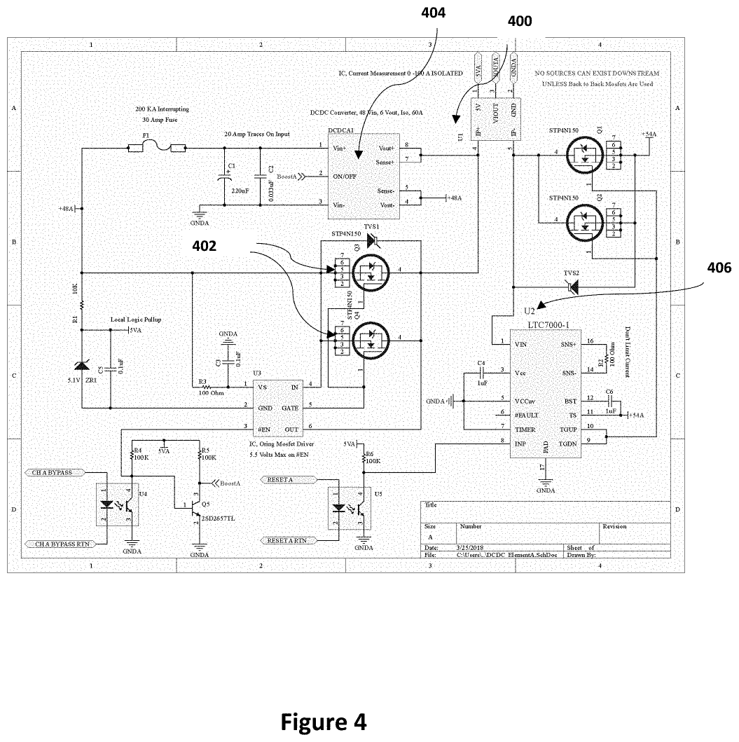

FIG. 4 shows a power module circuit 400 for a single 5V 60 A converter/booster module. Circuit 400 features include loop loss compensation using known resistance based on math/lookup tables.

In some embodiments, the Variable In Line Voltage Booster 100 may autonomously control boost voltage based on measured current and on Internal Resistance (IR) loss when compared to known values from math/lookup tables.

In some implementations, the power module circuit 400 can accommodate voltage oscillation when two power sources are present by the application of diodes with heat sinks.

The depicted power module circuit 400 allows for by-pass switching via MOSFET circuit 402 which also affords disconnection, selective power down and remote reset functionality to connected equipment. A suitable MOSFET circuit 402 may, for example, take the form of a power MOSFET available from STMicroelectronics under model number STP4N150.

The depicted power module circuit 400 can be arranged in multiples of “N” converters 404 in parallel and use a Hall effect sensor for control and allow for current sensing on each converter 404 to determine failure and provide redundancy and alarm capability.

The depicted power module circuit 400 allows for boost bypass configuration utilizing diodes or FETs optimized for parallel operation and limits current migration enabling operational fault awareness and tolerance.

The depicted power module circuit 400 may include a driver U2 which may allow for current measurement and fault diagnostic measurement. Additionally, the driver U2 can be used as a reset transistor driver circuit. A suitable driver U2 may take the form of a Fast 150V protected high side NMOS static switch driver, such as that available from Analog Devices under the product identifier LTC7000-1. The drive may, for example, be driven via an opto-isolator U5.

The depicted power module circuit 400 may include a transistor gate driver U3 which may be used to enable bypass functionality. The transistor gate driver U3 may be driven via an opto-isolator U4.

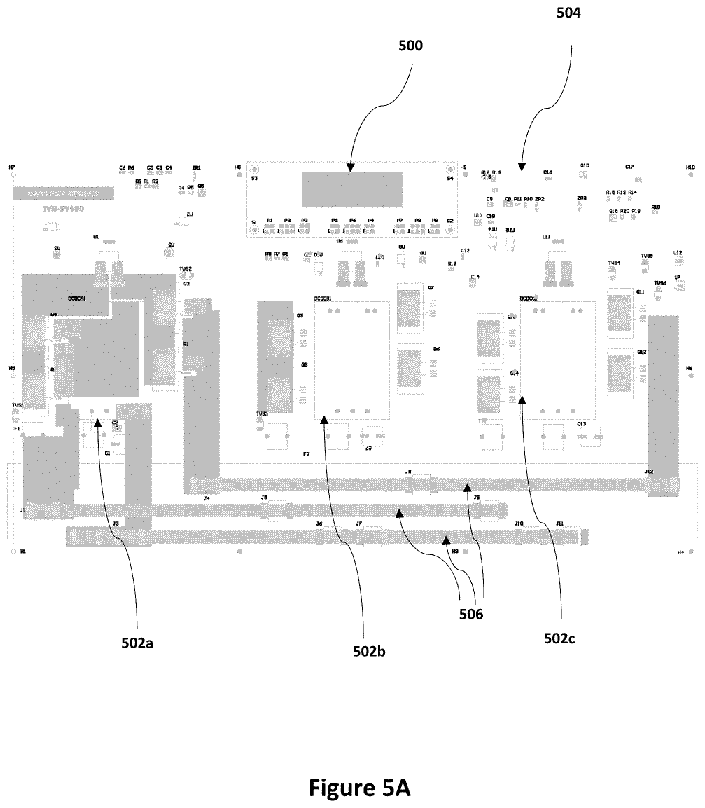

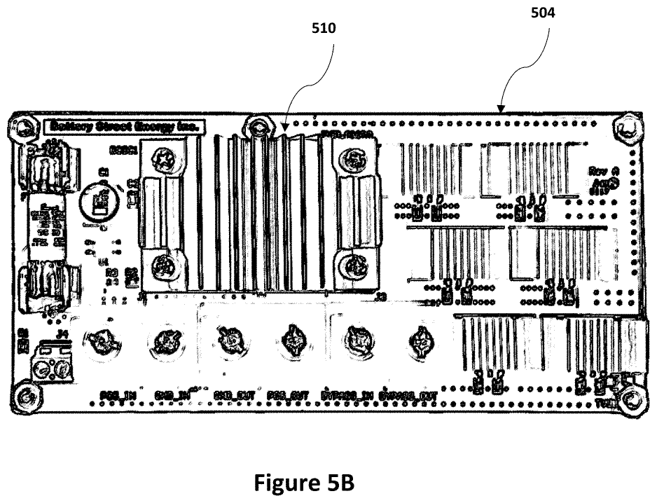

FIG. 5A shows a prototype PCB mask 500 for a single module with three 5V converters 502a, 502b, 502c (collectively 502) configured for a 180 A bulk feed.

On a circuit board substrate (e.g., fiberglass) or PCB 504, conductive traces 506 provide high current (e.g., wide traces) connections to carry the main current between an input port (e.g., DC board to wire connector). The PCB 504 depicted in FIG. 5A also includes signal traces that provide electrical connection, between components.

FIG. 5B shows a 60 A converter module with single 8V converters 510 on a PCB 504.

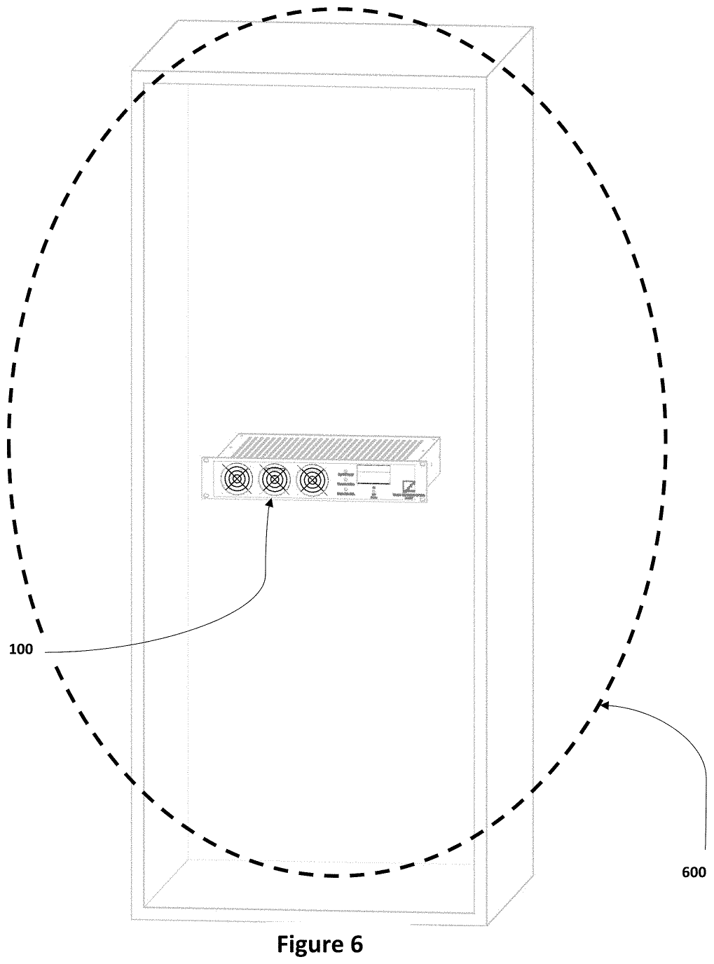

FIG. 6 shows a base station 600 in which one Variable In Line Voltage Booster 100 of FIG. 1A, is installed and ready for operation.

Some embodiments may cooperate with an external control device. In some embodiments, a control circuit, or other analog or digital power supply, may be included. In some embodiments, the control module 13 may provide audible and/or visual alarms, such as when circuit fault is detected or voltage/current flow falls outside of a predetermined normal operation.

Although various implementations and embodiments have been described with reference to the figures, other implementations and embodiments are possible. For example, some bypass circuits implementations may be controlled in response to signals from analog or digital components, which may be discrete, integrated, or a combination of each. Some embodiments may include programmed and/or programmable devices (e.g, PLAs, PLDs, ASICs, microcontroller, microprocessor), and may include one or more data stores (e.g., cell, register, block, page) that provide single or multi-level digital data storage capability, and which may be volatile and/or non-volatile. Some control functions may be implemented in hardware, software, firmware, or a combination of any of them.

Computer program products may contain a set of instructions that, when executed by a processor device, cause the processor to perform prescribed functions. These functions may be performed in conjunction with controlled devices in operable communication with the processor. Computer program products, which may include software, may be stored in a data store tangibly embedded on a storage medium, such as an electronic, magnetic, or rotating storage device, and may be fixed or removable (e.g., hard disk, floppy disk, thumb drive, CD, DVD).

A number of implementations and embodiments have been described. Nevertheless, it will be understood that various modification may be made. For example, advantageous results may be achieved if the acts of the disclosed techniques were performed in a different sequence, or if components of the disclosed systems were combined in a different manner, or if the components were supplemented with other components. Accordingly, other implementations are contemplated within the scope of this disclosure.

1. A single Variable In Line Voltage Booster, comprising:
a housing:
at least one set of input connectors;
at least one set of output connectors;
a plurality of power converters carried by at least one power converter board and coupled between the at least one set of input connectors and the at least one set of output connectors and operable to adjust a voltage received via the at least one set of input connectors to supply a voltage via the at least one set of output connectors; and
a control board carrying a set of control circuitry, the control circuitry communicatively coupled to control the plurality of power converters.

2. The single Variable In Line Voltage Booster of claim 1, further comprising:
a set of user accessible controls, the user accessible controls communicatively coupled to the control circuitry carried by the control board and operable to adjust at least one operational characteristic of the single Variable In Line Voltage Booster.

3. The single Variable In Line Voltage Booster of claim 2, further comprising:
a display carried by the housing an visible from an exterior thereof, the display operable to present information about at least one operational characteristic of the single Variable In Line Voltage Booster.

4. The single Variable In Line Voltage Booster of claim 1, further comprising:
a plurality of exhaust vents formed in the housing.

5. The single Variable In Line Voltage Booster of claim 1, further comprising:
a number of inlet vents formed in the housing.

6. The single Variable In Line Voltage Booster of claim 5, further comprising:
at least one inlet fan, the at least one inlet fan positioned coaxially with a respective one of the inlet vents.

7. The single Variable In Line Voltage Booster of claim 6 wherein the inlet vents formed in a front face of the housing.

8. The single Variable In Line Voltage Booster of claim 4 wherein the plurality of exhaust vents formed in the housing are in a top of the housing.

9. The single Variable In Line Voltage Booster of claim 8, further comprising:
a further exhaust vent positioned in a rear face of the housing; and
an exhaust fan positioned coaxially with the further exhaust vent.

10. The single Variable In Line Voltage Booster of claim 1, further comprising:
a set of posts, wherein the control board is spaced relative above the by at least one power converter board by the set of posts.

11. The single Variable In Line Voltage Booster of claim 1, further comprising:
a set of boost connectors electrically coupled to at least one power converter board.

12. The single Variable In Line Voltage Booster of claim 1 wherein the housing is a rack mountable housing.
